(19) United States
(12) Patent Application Publication
(10) Pub. No.: US 2011/0108985 A1
(43) Pub. Date: May 12, 2011

(54) SEMICONDUCTOR DEVICE AND METHOD FOR MANUFACTURING THE SAME

(75) Inventor: Seung Hwan KIM, Seoul (KR)

(73) Assignee: Hynix Semiconductor Inc., Icheon (KR)

(21) Appl. No.: 12/816,274

(22) Filed: Jun. 15, 2010

(30) Foreign Application Priority Data
Nov. 10, 2009 (KR) 10-2009-0108121

(51) Int. Cl. H01L 23/535; H01L 21/22

(52) U.S. Cl. 257/751; 438/564; 257/E21.135; 257/E23.168

(57) ABSTRACT

A method for manufacturing a semiconductor device comprises: etching a semiconductor substrate to form a plurality of pillar patterns; depositing an insulating layer on the surface of the pillar pattern; removing a portion of the insulating layer located at one side of the pillar pattern to form a contact hole that exposes the pillar pattern; forming a barrier film in the contact hole; and forming a junction in the pillar pattern that contacts with the contact hole. In the method, when a buried bit line is formed, a diffusion barrier is formed in the contact hole and a junction is formed in the lower portion of the pillar pattern, thereby improving characteristics of the device.

### CROSS-REFERENCE TO RELATED APPLICATION

The priority of Korean patent application No. 10-2009-108121 filed on Nov. 10, 2009, the disclosure of which is hereby incorporated in its entirety by reference, is claimed.

### BACKGROUND OF THE INVENTION

An embodiment of the present invention relates to a semiconductor device and a method for manufacturing the same that comprises a vertical channel transistor.

Due to an increase in the integration of semiconductor devices, a channel length of a transistor is gradually reduced. However, the reduction in the channel length of the transistor may cause short channel effects such as a Drain Induced Barrier Lowering (DIBL) phenomenon, a is hot carrier effect and a punch-through phenomenon. In order to prevent the short channel effects, various methods have been proposed such as a method of reducing a depth of a junction region or a method of increasing a channel length by forming a recess in a channel region of the transistor.

However, as the integration density of the semiconductor memory device, specifically, DRAM, has edged up to giga bit density, the manufacturing of smaller-sized transistors is required. That is, the transistor of the giga-bit DRAM requires the device area of less than 8F2 (F: minimum feature size), and further requires the device area of 4F2. As a result, it is difficult to satisfy the required device area with the structure of the current plannar transistor having a gate electrode formed on a semiconductor substrate and a junction region formed at both sides of the gate electrode even though the channel length is subject to scaling. In order to solve this problem, a vertical channel transistor is suggested.

Although it is not shown, a method for manufacturing a vertical channel transistor is as follows. A cell region of a semiconductor substrate is etched with a given depth by a photo lithography process to form a top pillar and form a spacer that surrounds a sidewall of the top pillar. The exposed semiconductor substrate is further etched with the spacer as an etching mask to form a trench. An isotropic wet etching process is performed on the trench to form a neck pillar that constitutes an integral structure with the top pillar and extends in a vertical direction. The neck pillar is formed to have a narrower width than that of the top pillar. A gate insulating film and a surrounding gate that includes a conductive film are formed at the outside sidewalls of the neck pillar. An ion-implantation process is performed on the semiconductor substrate adjacent to the surrounding gate to form a bit line impurity region. The semiconductor substrate is etched to the depth separated from the impurity region to form a buried bit line apart from the impurity region. In order to prevent a short between the buried bit lines, the semiconductor substrate is required to be deeply etched. Subsequent processes are performed in sequence to obtain a semiconductor device having a vertical transistor according to the prior art.

However, the method of etching the semiconductor substrate to separate the buried bit line decreases the integration of the semiconductor device. As a result, it is difficult to secure a dimension required in performing the corresponding process as the width of the buried bit line becomes smaller.

Also, when a high-concentrated ion-implantation process is performed directly on a silicon substrate when forming the buried bit line, a floating phenomenon can occur. The floating phenomenon is causes by the diffusion of impurities, which degrades the performance of the transistor. If the doping concentration of the ion-implantation process is reduced in order to improve the performance of the transistor, resistance of the buried bit line increases.

In order to prevent the increase of the resistance, a method of forming a bit line contact only at one side of the pillar has been suggested. However, during the process of forming a junction in the lower portion between pillars, the junction area increases by a thermal treatment which increases the occurrence of Drain Induced Barrier Lowering (DIBL) and increases leakage current between cells.

### BRIEF SUMMARY OF THE INVENTION

Various embodiments of the invention are directed to forming a stable contact, reducing resistance of a buried bit line, forming a diffusion barrier in a buried bit line contact hole and forming a shallow junction.

According to an embodiment of the present invention, a method for manufacturing a semiconductor device comprises: etching a semiconductor substrate to form a plurality of pillar patterns; depositing an insulating layer on the surface of the pillar pattern; removing a portion of the insulating layer located at one side of the pillar pattern to form a contact hole that exposes the pillar pattern; forming a barrier film in the contact hole; and forming a junction in the pillar pattern that contacts with the contact hole.

The insulating layer includes a nitride film. The barrier film includes a TiSi₂ film. The forming-a-barrier-film includes: forming a Ti film on the surface of the insulating layer where the contact hole is formed; and converting the Ti film contacting with the pillar pattern exposed by the contact hole into the TiSi₂ film. The forming-a-Ti-film includes performing a plasma enhanced chemical vapor deposition (PECVD) process using TiCl₄. The PECVD process is performed at a temperature ranging from about 650 to about 850° C.

The method further comprises depositing a TiN film on the surface of the Ti film. The forming-a-junction includes: forming a polysilicon layer on the upper portion of the pillar pattern; and performing an annealing process to diffuse dopants in the polysilicon layer into the inside of the pillar pattern. The polysilicon layer is a doped silicon. The doped polysilicon is formed by doping phosphorous ions. The annealing process is performed by a furnace or a rapid thermal annealing (RTA) process.

After forming a junction in the pillar pattern that contacts with the contact hole, the method further comprises: forming a bit line material layer on the overall upper portion of the pillar pattern; and performing an etch-back process to form a buried bit line in the lower portion of between the pillar patterns. The bit line material layer includes one selected from the group consisting of tungsten, TiN and combinations thereof.

According to an embodiment of the present invention, a semiconductor device comprises: a plurality of pillar patterns; a contact hole formed at one side of the pillar pattern; a barrier film buried in the contact hole; and a junction formed in the pillar pattern that contacts with the contact hole.

The contact hole has a shape where the pillar pattern is exposed by an insulating layer formed on the surface of the pillar pattern. The barrier film includes TiSi₂. The semiconductor device further comprises a Ti film and a TiN film on the surface of the pillar pattern. The is semiconductor device further comprises a buried bit line formed to contact with the contact hole in the lower portion between the pillar patterns. The buried bit line includes one selected from the group consisting of tungsten, TiN and combinations thereof.

### BRIEF DESCRIPTION OF THE DRAWINGS

FIGS. 1a to 1i are perspective views illustrating a method for manufacturing a semiconductor device according to an embodiment of the present invention.

### DESCRIPTION OF EMBODIMENTS

The embodiments of the present invention will be described in detail with reference to the attached drawings.

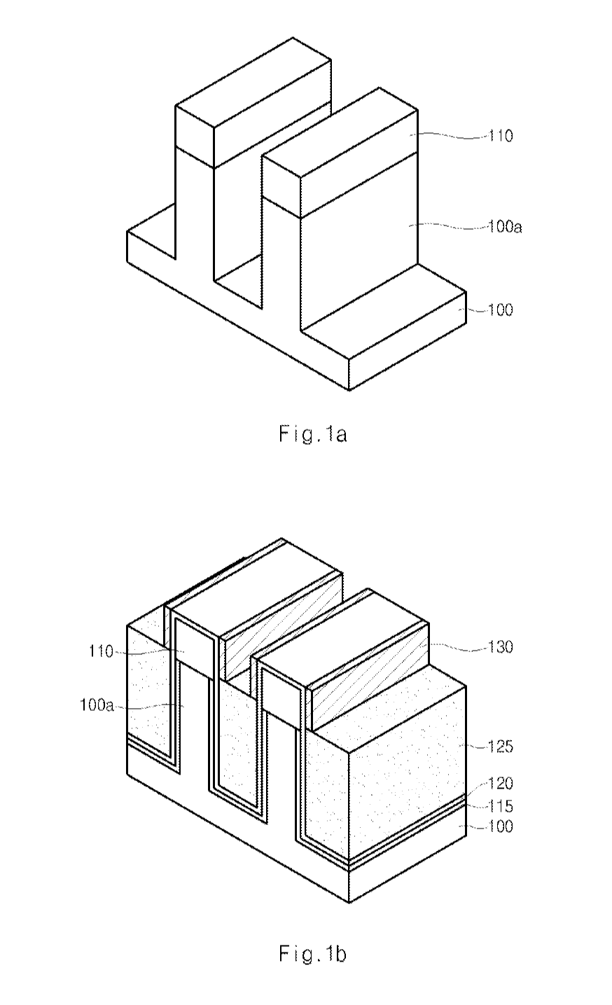

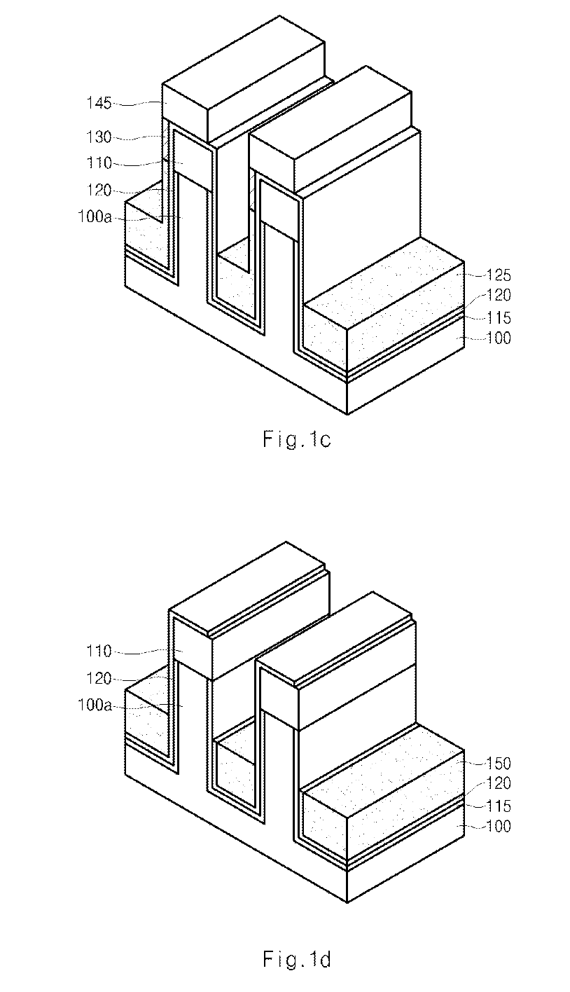

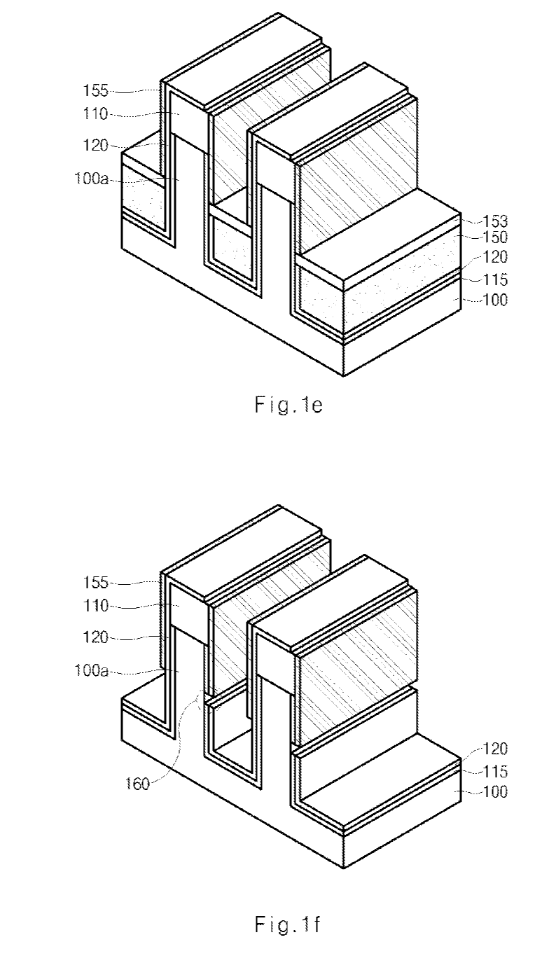

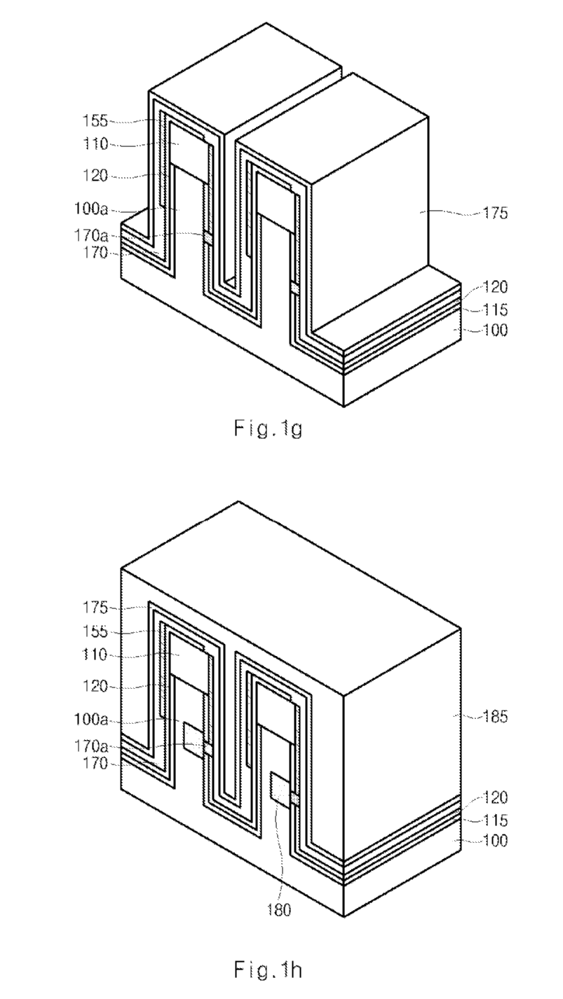

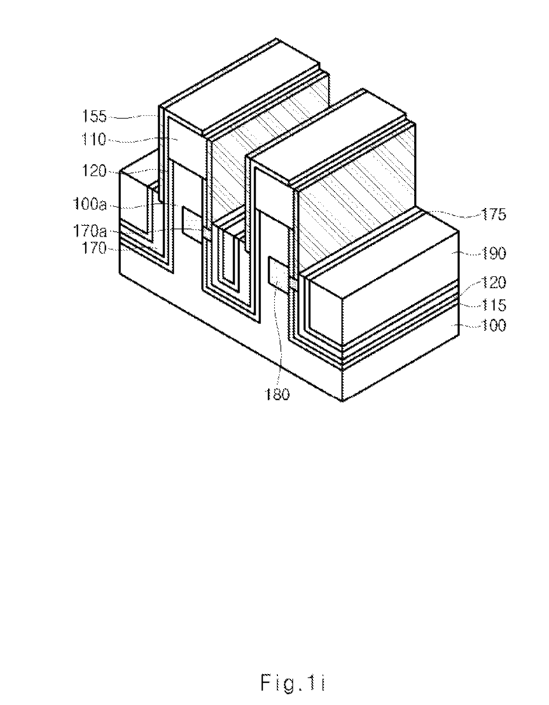

FIGS. 1a to 1i are perspective views showing a method for manufacturing a semiconductor device according to an embodiment of the present invention.

Referring to FIG. 1a, a hard mask layer (not shown) is formed on a semiconductor substrate 100. The hard mask layer (not shown) may be formed of an amorphous carbon layer, a silicon oxide nitride (SiON) film or an amorphous silicon (a-Si) layer.

The hard mask layer (not shown) is patterned to form a hard mask pattern 110 that defines a buried bit line region. The semiconductor substrate 100 is etched with the hard mask pattern 110 as a mask to form a plurality of pillar patterns 100a. The pillar pattern 100a is obtained in a vertical direction by etching a portion of the semiconductor substrate 100.

An oxidation process is performed to form an oxide film 115 on the surface of the semiconductor substrate 100 and the pillar pattern 100a. Since the oxidation process reacts with a silicon layer, the surface covered by the hard mask pattern 110 is not oxidized. A nitride film 120 is deposited on the surface of the semiconductor substrate 100 including the hard mask pattern 110 and the pillar pattern 100a.

Referring to FIG. 1b, a first polysilicon layer 125 is formed on the overall upper portion of the resultant structure including the pillar pattern 100a and the hard mask pattern 110 where the nitride film 120 is formed. The first polysilicon layer 125 which includes undoped polysilicon is formed to a height where the hard mask pattern 110 is not exposed.

A Chemical Mechanical Polishing (CMP) process is performed to expose the nitride film 120 disposed at the top side of the hard mask pattern 110. The first polysilicon layer 125 is etched by an etch-back process. As a result, a portion of the hard mask pattern 110 is protruded from the top portion of the first polysilicon layer 125. After a liner oxide film (not shown) and a liner nitride film (not shown) are deposited on the top portion of the first polysilicon layer 125 and the exposed nitride film 120, an etch-back is performed to form a first spacer 130 on the sidewall surface of the nitride film 120.

Referring to FIG. 1c, a photoresist pattern 145 to open a bit line contact region is formed on the top portion of the first spacer 130 and the nitride film 120. The bit line contact is formed at one side surface of the pillar pattern 100a. The photoresist pattern 145 removes the first is spacer 130 disposed at one side surface of the hard mask pattern 110, and does not remove the first spacer 130 disposed at the opposite side surface of the hard mask pattern 110. The first spacer 130 and the first polysilicon layer 125 are etched with the photoresist pattern 145 as a mask. The first polysilicon layer 125 is etched to expose a region where a contact hole is formed.

Referring to FIG. 1d, the photoresist pattern 145 and the first spacer 130 are removed. When the first spacer 130 is removed, the nitride film 120 disposed at one side surface of the hard mask pattern 110 and the pillar pattern 100a is simultaneously patterned by a given depth to form a second poly-silicon layer 150. The first polysilicon layer 125 that remains on the opposite side surface of the pillar pattern 100a is also patterned by a give depth to form the second poly-silicon layer 150. As a result, the oxide film 115 remains on one side surface of the pillar pattern 100a, but both the oxide film 115 and the nitride film 120 remains on the other side of the pillar pattern 100a. The second polysilicon layer 150 is present between the pillar patterns 100a. The second polysilicon layer 150 is formed lower than the top of the pillar pattern 100a.

Referring to FIG. 1e, a third polysilicon layer 153 is deposited on the upper portion of the second polysilicon layer 150. A liner nitride film (not shown) is formed on the overall upper portion including the third polysilicon layer 153, the pillar pattern 100a and the hard mask pattern 110. By performing an etch-back process onto the liner nitride film (not shown), a second spacer 155 is formed at the sidewalls of the hard mask pattern 110 and the pillar pattern 100a.

Referring to FIG. 1f, the third polysilicon layer 153 and the second polysilicon layer 150 are removed, thus forming a first contact hole over one sidewall of the pillar 100a. In the present embodiment, the first contact hole is only located at one sidewall of the pillar pattern 100a, and exposes the oxide film 115. A cleaning process is performed to remove the oxide film 115 exposed by the first contact hole, thereby forming a second contact hole 160 extending from the first contact hole. The second contact hole 160 exposes the sidewalls of the underlying pillar pattern 100a.

Referring to FIG. 1g, a metal film, for example, a Ti film 170 is deposited on the surface of the hard mask pattern 110 and the pillar pattern 100a including the contact hole 160 by a plasma enhanced chemical vapor deposition (PE-CVD) process using TiCl₄. Since the PE-CVD process is perform at a high temperature ranging from about 650 to about 850° C. and the thickness of the Ti film 170 ranges from about 20 to about 30 Å. The Ti film 170 reacts with the exposed pillar pattern 100a to form a TiSi₂ film 170a on the pillar 110a in the second contact hole 160. That is, the TiSi₂ film 170a is formed in the contact hole 160. At the same time, the Ti film 170 reacts with the exposed pillar 100a, which is transformed into a TiSi₂ film 170a. That is, the TiSi₂ film 170a is buried in the contact hole 160. However, the Ti film 170 is disposed in the portion except the contact hole 160. A TiN film 175 is deposited on the surface of is the Ti film 170. The thickness of the TiN film 175 ranges from about 30 to about 40 Å.

Referring to FIG. 1h, a fourth polysilicon layer 185 is formed on the overall upper portion including the hard mask pattern 110 and the pillar pattern 100a. The fourth polysilicon layer 185 may be formed of a doped-polysilicon layer which is doped with phosphorous ions. An annealing process is performed to diffuse dopants from the fourth polysilicon layer 185 into the inside of the pillar pattern 100a, thereby forming a junction (or junction region) 180. The annealing process is performed with a furnace or a rapid thermal annealing (RTA) process. The junction 180 is formed under the TiSi₂ film 170a in the pillar pattern 100a. The junction 180 may reduce resistance of the TiSi₂ film 170a. Also, the shallow junction can be formed because TiSi₂ film 170a is used as a diffusion barrier.

Referring to FIG. 1i, the fourth polysilicon layer 185 is patterned by a dry or wet etching process. More preferably, after the dry etching process is performed, a wet etching process is further done to remove the fourth polysilicon layer 185 completely.

The TiSi₂ film 170a is protected from the dry or wet etching process by the TiN film 175. As a result, a stable contact between the bit line 190 and the pillar pattern 100a where a channel is formed can be formed. Then, a bit line material layer is formed on the overall upper portion including the hard mask pattern 110 and the pillar pattern 100a. The bit line material layer includes tungsten or a TiN film. The bit line is material layer is etched to the top side of the contact hole 160, thereby forming a buried bit line 190 that contacts the TiSi₂ film 170a. When the buried bit line 190 includes tungsten or a Ti film, the resistance can be reduced.

Referring to FIG. 1i, a semiconductor device having a buried bit line 190 is described as follows. A plurality of pillar patterns 100a are formed in the semiconductor substrate 100. The hard mask pattern 110 is formed over the pillar pattern 100a. The nitride film 120 is deposited on the surface of the hard mask pattern 110 and the pillar pattern 100a. The nitride film 120 is removed at one side of the pillar pattern 100a, thereby forming a contact hole that exposes the pillar pattern 100a. The contact hole is filled with the TiSi₂ film 170a. The junction 180 is formed in the pillar pattern 100a under the TiSi₂ film 170a.

The Ti film 170 and the TiN film 175 are deposited on the overall surface of the hard mask pattern 110 and the pillar pattern 100a that includes the shallow junction 180. The buried bit line 190 that contacts the shallow junction 180 through the TiSi₂ film 170a is formed on the lower portion between the pillar patterns 100a. The buried bit line 190 is preferably formed of tungsten or a TiN film 175.

As described above, a semiconductor device and a method for manufacturing the same according to an embodiment of the present invention have the following effects. First, the resistance of the buried bit line 190 can be reduced because of the TiSi₂ film 170a formed between the buried bit line 190 and the pillar pattern 100a. The TiSi₂ film 170a is electrically couples the buried bit line 190 to the pillar pattern 100a. The TiSi₂ film serves as a diffusion barrier between the pillar pattern 100a and the buried bit line 190 can be formed because of the shallow junction formed in the sidewall of the pillar pattern 100a and electrically connected to the buried bit line 190. Second, a stable contact between the pillar pattern 100a and the bit line pattern 190 because of the TiSi₂ film 170a is protected from the dry or wet etching process by the TiN film 175. Third, the resistance can be further reduced when the buried bit line 190 is formed of tungsten or a TiN film.

The above embodiments of the present invention are illustrative and not limitative. Various alternatives and equivalents are possible. The invention is not limited by the type of deposition, etching polishing, and patterning steps describe herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A method for manufacturing a semiconductor device, the method comprising:
etching a semiconductor substrate to form a pillar pattern;
depositing an insulating layer over a surface of the pillar pattern;
removing a portion of the insulating layer located at a sidewall of the pillar pattern to form a contact hole, the contact hole exposing and defining a portion of the sidewall of the pillar pattern;
forming a barrier film within the contact hole;
forming a junction region in the portion of the sidewall of the pillar pattern defined by the contact hole; and
forming a bit line over the barrier film to electrically couple the junction.

2. The method according to claim 1, wherein the insulating layer includes a nitride film.

3. The method according to claim 1, wherein the barrier film includes a TiSi₂ film.

4. The method according to claim 3, wherein the forming-a-barrier-film includes:
forming a titanium film over the surface of the insulating layer where the contact hole is formed; and
converting the titanium film contacting the portion of the sidewall of the pillar pattern defined by the contact hole into the TiSi₂ film.

5. The method according to claim 4, wherein the forming-a-Ti-film includes performing a plasma enhanced chemical vapor deposition (PECVD) process using TiCl₄.

6. The method according to claim 5, wherein the PECVD process is performed at a temperature ranging from about 650 to about 850° C.

7. The method according to claim 4, further comprising depositing a TiN film on a surface of the Ti film.

8. The method according to claim 1, wherein the forming-a-junction includes:
forming a polysilicon layer over an upper portion of the pillar pattern; and
performing an annealing process to diffuse dopants in the polysilicon layer into the pillar pattern.

9. The method according to claim 8, wherein the polysilicon is layer is a doped silicon layer.

10. The method according to claim 9, wherein the doped polysilicon layer includes phosphorous.

11. The method according to claim 8, wherein the annealing process is performed by a furnace or a rapid thermal annealing (RTA) process.

12. The method according to claim 1, wherein the bit line forming step comprising:
after forming the junction region in the sidewall of the pillar pattern, forming a bit line material layer on an upper portion of the pillar pattern, and performing an etch-back process to form the bit line in a lower portion of the pillar pattern.

13. The method according to claim 12, wherein the bit line material layer includes one selected from the group consisting of tungsten, TiN and a combination thereof.

14. A semiconductor device comprising:
a first pillar defined on a substrate, the first pillar having a sidewall extending vertically from the substrate;
an insulating layer formed conformally over the first pillar;
a contact hole extending through the insulating layer to expose a portion of the sidewall of the first pillar;
a barrier film formed within the contact hole; and
a junction region formed in the portion of the sidewall of the first pillar pattern.

15. The semiconductor device according to claim 14, wherein the junction region extends laterally into the first pillar from the portion of the sidewall of the first pillar and the barrier film.

16. The semiconductor device according to claim 14, wherein the barrier film includes TiSi₂.

17. The semiconductor device according to claim 14, further comprising a Ti film and a TiN film on a surface of the first pillar.

18. The semiconductor device according to claim 14, further comprising:
a second pillar adjacent to the first pillar;
a buried bit line formed between the first and second pillars and contacting the contact hole.

19. The semiconductor device according to claim 18, wherein the buried bit line includes one selected from the group consisting of tungsten, TiN and combinations thereof.
